(19) United States
(12) Patent Application Publication
(10) Pub. No.: US 2020/0144473 A1
(43) Pub. Date: May 7, 2020

(54) THERMOELECTRIC CONVERSION ELEMENT

(71) Applicant: FUJITSU LIMITED, Kawasaki-shi (JP)

(72) Inventors: John David BANIECKI, Zama (JP); Hiroyuki ASO, Atsugi (JP); Yasutoshi KOTAKA, Sagamihara (JP); Yoshihiko IMANAKA, Atsugi (JP)

(73) Assignee: FUJITSU LIMITED, Kawasaki-shi (JP)

(21) Appl. No.: 16/569,349

(22) Filed: Sep. 12, 2019

Related U.S. Application Data
(62) Division of application No. 15/064,003, filed on Mar. 8, 2016, now abandoned.

(30) Foreign Application Priority Data
Mar. 9, 2015 (JP) 2015-046131

(51) Int. Cl. H01L 35/22; H01L 35/34; H01L 35/10

(52) U.S. Cl. CPC H01L 35/22; H01L 35/10; H01L 35/34

(57) ABSTRACT

A thermoelectric conversion element includes: a first layer of perovskite-type oxide has conductivity or semiconductivity; a second layer of perovskite-type oxide that is disposed in contact with the first layer in a stacking direction; and an electrode disposed on a surface of the second layer, wherein the second layer has a band gap larger than a band gap of the first layer and has transition lines penetrating through the second layer in a film thickness direction or a transition line network.

### CROSS-REFERENCE TO RELATED APPLICATION

This application is a divisional of U.S. application Ser. No. 15/064,003, filed Mar. 8, 2016, which claims priority to Japanese Patent Application No. 2015-046131, filed Mar. 9, 2015, the entire contents of which are incorporated herein by reference.

### FIELD

The embodiments discussed herein are related to a thermoelectric conversion element, a thermoelectric conversion module and a method for manufacturing the thermoelectric conversion element.

### BACKGROUND

Although most of used energy has been so far discharged into the environments as waste heat, a heat/electricity conversion technique for converting the waste heat into electric energy has been recently attracting attention. A thermoelectric (TE) material is a material that enables heat discharged from power plants, automobiles, computers, wearable biological monitors and so on to be converted into electric energy and reused. Conventional thermoelectric systems have used a high temperature fluid as a heat source and have an operation unit having a complicated configuration. In contrast, a leg-type solid thermoelectric system has a simple structure of connecting a P-type leg and an N-type leg to each other by an electrode and may manufacture a thermoelectric conversion element with a certain size, thereby providing the possibility of a variety of applications. In addition, researches on forming a thermoelectric element as a thin film are underway.

It is common that bismuth-telluride-based materials and semiconductor materials are used as solid-sate thermoelectric materials. However, it is difficult for these materials to obtain sufficient conversion efficiency as compared with the energy conversion system that uses a fluid. Further, there is another problem that tellurium and bismuth are toxic and rare natural resources having limited reserves.

Strontium titanate (SrTiO₃: appropriately abbreviated as “STO”) is attracting attention as a thermoelectric material because of its non-toxicity. The performance of a thermoelectric material depends on an operation temperature. Therefore, a dimensionless performance index ZT (=S²σ/κ), which is a product of the performance index Z of the thermoelectric material and the absolute temperature, is used as an indicator of an energy conversion efficiency. Where, S is a Seebeck coefficient of the thermoelectric material (or thermopower), σ is conductivity, and κ is thermal conductivity. A material having a high Seebeck coefficient S, high conductivity σ, and low thermal conductivity κ is superior as the thermoelectric material. SrTiO₃ has a high power factor PF (═S²σ) of 35 to 40 μW/cmK².

However, since most systems have high thermal conductivity κ, the performance index ZT (═S²σ/κ) is limited, and it is difficult to achieve a ZT value which can be applied to devices at the room temperature. In addition, there has been proposed a method of increasing a ZT value by means of a thermoelectric material using nano-particles having the average diameter smaller than the normal granularity.

One of methods useful to increase the energy conversion efficiency is to use quantum confinement of charge carriers. For example, an insulating film having a larger band gap than STO is formed on a STO thin film doped with impurities, and carriers are confined in the STO thin film serving as a thermoelectric material. However, a material having a large barrier for carrier confinement interferes with the contact with a conductive region (thermoelectric material).

The followings are reference documents.

[Document 1] Japanese Laid-Open Patent Publication No. 2010-161213,

[Document 2] Japanese Laid-Open Patent Publication No. 05-198847 and

[Document 3]Japanese Laid-Open Patent Publication No. 2012-248845.

### SUMMARY

According to an aspect of the invention, a thermoelectric conversion element includes: a first layer of perovskite-type oxide has conductivity or semiconductivity; a second layer of perovskite-type oxide that is disposed in contact with the first layer in a stacking direction; and an electrode disposed on a surface of the second layer, wherein the second layer has a band gap larger than a band gap of the first layer and has transition lines penetrating through the second layer in a film thickness direction or a transition line network.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed,

### BRIEF DESCRIPTION OF DRAWINGS

FIGS. 1A and 1B are views for explaining technical problems which may occur in a process leading to an embodiment;

FIGS. 2A and 2B are views for explaining a configuration of a thermoelectric conversion element according to an embodiment;

FIG. 3 is a STEM image of the thermoelectric conversion element of FIGS. 2A and 2B;

FIGS. 4A and 4B are views illustrating a STEM image of a SZO layer 27 of thickness of 4 nm formed on a STO film and a spectrum of an X-ray diffraction Φ scan, as a comparative example;

FIG. 5 is a view illustrating a relationship between the film thickness and a sheet resistance of the SZO layer in the hetero structure of FIGS. 2A and 2B;

FIG. 6 illustrates a configuration of a sample for making measurement of FIG. 5;

FIG. 7 is a view illustrating a relationship between the film thickness and a sheet resistance of the SZO layer when the thickness of the underlying La-STO layer is changed;

FIG. 8 is a view illustrating a relationship between the thickness of the La-STO layer and a Seebeck coefficient S, in comparison with a bulk La-STO;

FIGS. 9A and 9B are schematic views of a thin film-type thermoelectric conversion module to which the thermoelectric conversion element of the embodiment is applied; and

FIGS. 10A and 10B illustrate the operation principle of the thermoelectric conversion module and an example of application of the thermoelectric conversion module.

### DESCRIPTION OF EMBODIMENTS

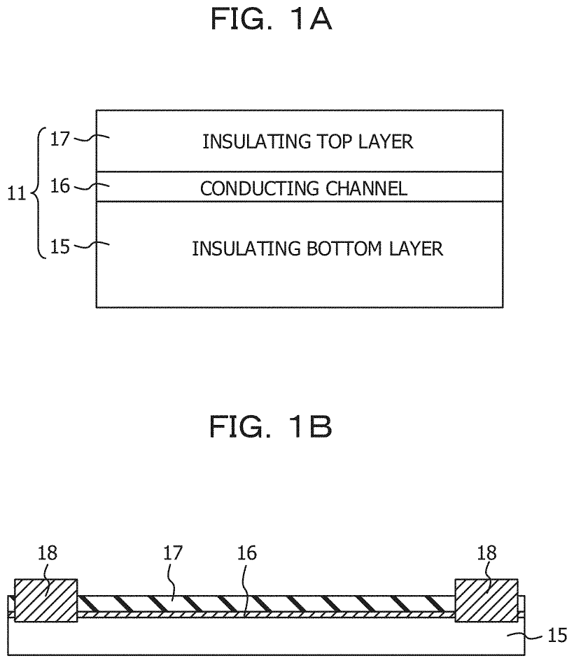

Prior to description about an embodiment, problems which may occur in a process leading to the embodiment will be described with reference to FIGS. 1A and 1B. A thermoelectric conversion material 11 illustrated in FIG. 1A includes a lower insulating layer 15, an upper insulating layer 17, and an N-type conductive or semi-conductive perovskite-type oxide layer 16 interposed therebetween. For example, the conductive or semi-conductive oxide layer 16 is a thin film of SrTiO₃ doped with lanthanum (La) (appropriately abbreviated as “La-STO”). The upper insulating layer 17 and the lower insulating layer 15 are perovskite-type oxide layers having a bandgap larger than that of SrTiO₃. Electrons are confined in the La-STO layer 16 by the hetero structure including the lower insulating layer 15, the La-STO layer 16, and the upper insulating layer 17. Electrons in a hot area are activated by heating to form a conducting channel. This may obtain an effect similar to a two dimensional electron gas (2DEG), thereby achieving an improved thermoelectric conversion capability. In a case of a P-type thermoelectric material, holes are activated by heating and are diffused into a two dimensional shape.

The configuration of FIG. 1A uses a through-electrode for making a contact with the conducting channel. For example, as illustrated in FIG. 1B, an electrode 18 is formed to be electrically connected to the La-STO layer 16 through the upper insulating layer 17. The confined electrons move into the in-plane direction of the La-STO layer 16 but do not move into the vertical (film thickness) direction thereof. This is because the confined electrons cannot contact the top surface of the upper insulating layer 17. Machining such as dicing may be performed to form the electrode 18 penetrating through the upper insulating layer 17. However, it is difficult to perform a highly accurate machining for a small surface area. In addition, there is a possibility that an element is adversely affected in the course of the machining. Therefore, there is a need for a simple contact configuration.

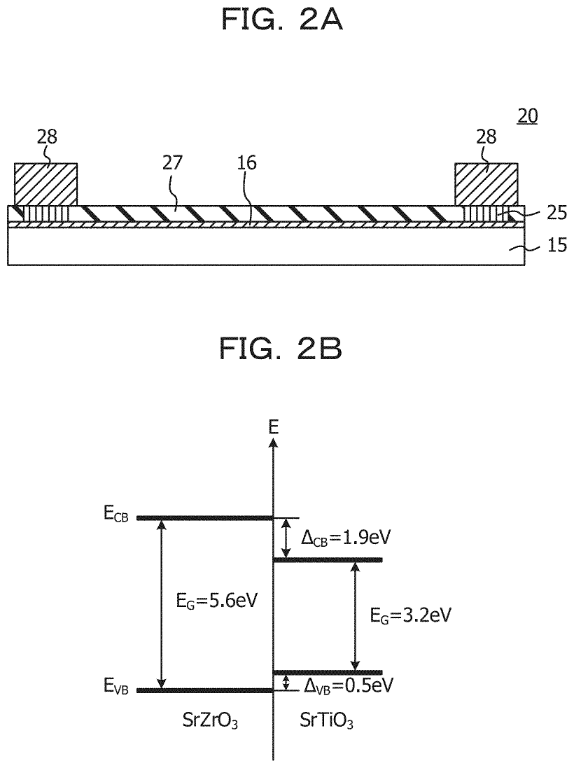

FIGS. 2A and 2B are schematic views of an N-type region of a thermoelectric conversion element 20 according to an embodiment. The thermoelectric conversion element 20 includes a lower insulating layer 15, a second insulating layer 27, and a conductive or semi-conductive oxide layer 16 interposed therebetween. For example, the oxide layer 16 is a thin film of SrTiO₃ doped with La (La-STO). For example, the lower insulating layer 15 is a substrate 15 of (La, Sr)(Al, Ta)O₃ (hereinafter abbreviated as “LSAT”). The LSAT substrate 15 may be used as a growth substrate of the La-STO layer 16.

The second layer 27 is a perovskite-type oxide layer having a bandgap larger than that of SrTiO₃. In this embodiment, the second layer 27 is a strontium zirconate (SrZrO₃) layer (hereinafter appropriately abbreviated as a “SZO layer 27”).

As one feature of the embodiment, the SZO layer 27 has a plurality of transition lines penetrating through the SZO layer 27 in the film thickness direction. The transition lines 25 provide the SZO layer 27 with an insulating property in the in-plane direction and with conductivity in the film thickness direction (a direction perpendicular to the plane). The number of transition lines penetrating through the SZO layer 27 in the film thickness direction may not necessarily be one. The plurality of transition lines 25 may be a transition line network connecting the space between the top and bottom of the SZO layer 27 in the film thickness direction. By controlling the film thickness of the SZO layer 27, it is possible to obtain a good conductivity in the film thickness direction without relying on the film thickness of the underlying La-STO layer 16. The thickness of the SZO layer 27 is in the range of 10 nm to 25 nm, and may be in the range of 15 nm to 20 nm. When the thickness of the SZO layer 27 is set to fall within this range, it is possible to make the sheet resistance to be zero or near zero while maintaining the insulating property of the SZO layer 27 in the in-plane direction.

As illustrated in FIG. 2B, there is a large band offset between SrZrO₃ and SrTiO₃. An energy gap Δ_{VB} in the upper end of the valence band is 0.5 eV and an energy gap Δ_{CB} in the lower end of the conduction band is 1.9 eV. Usually, no stack-wise conduction occurs between the STO layer 16 and the SZO layer 27. In this embodiment, the conduction of the SZO layer 27 in the thickness direction is achieved by adjusting the thickness of the SZO layer 27 to a thickness through which a filament-type transition path penetrates. When transition lines of perovskite-type oxide are used for electrode contact, it is possible to make a contact of the surface of the SZO layer 27 with the underlying La-STO layer 16.

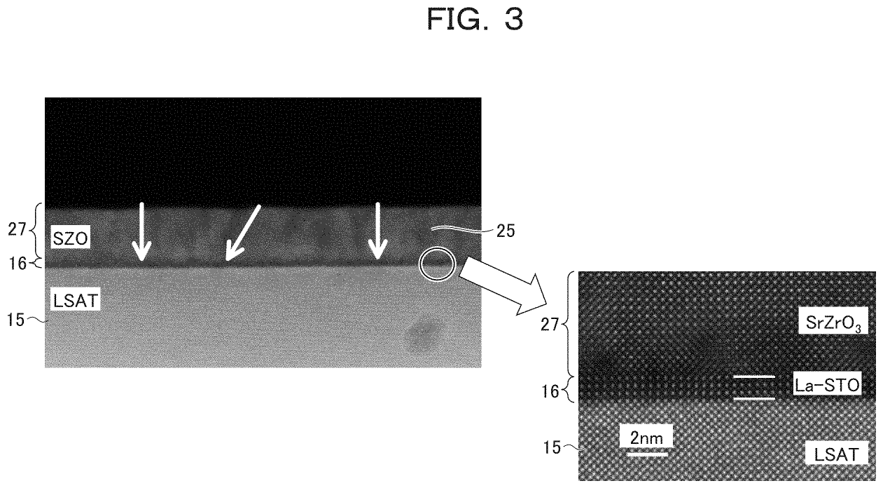

FIG. 3 is a Scanning Transmission Electron Microscope (STEM) image of the configuration of FIGS. 2A and 2B. The La-STO layer 16 of 4 ML (monolayer) and the SZO layer 27 of a thickness of 18 nm are sequentially grown on the LSAT substrate 15 of a (001) plane. The La-STO layer 16 is formed, for example, by a Pulse Laser Deposition (PLD). For example, a Q switch Nd-YAG laser (available from Alma Co., Ltd.) irradiates a La-doped single crystal SrTiO₃ target with a pulse rate of 10 Hz and a pulse fluence of 1.6 J/cm². A deposition temperature is 600° C. and an oxygen pressure is 1 milli-Torr (0.3 Pa). With these conditions, a deposition speed is 1.8 nm/min, which corresponds to a thickness of 4 ML (1.6 nm) at 53 seconds.

The SZO layer 27 is epitaxially grown on the La-STO layer 16, for example, by the PLD. The Q switch Nd-YAG laser (available from Alma Co., Ltd.) irradiates a ceramic SrZrO₃ target with a pulse rate of 10 Hz and a pulse fluence of 0.62 J/cm². A deposition temperature is in the range of 570° C. to 620° C. and an oxygen pressure is 50 milli-Torr (about 6.5 Pa). With these conditions, a deposition speed is 0.35 nm/min to 0.38 nm/min, which corresponds to a thickness of 18 nm at 47 minutes to 50 minutes.

As indicated by arrows in FIG. 3, transition lines 25 (or a network of transition lines 25) penetrating through the SZO layer 27 are observed in the SZO layer 27. A region indicated by a circle is an interface region of the SZO layer 27, the La-STO layer 16, and the LSAT substrate 15 (e.g., a hetero structure). In the SZO layer 27, the white points indicate Sr and the black points indicate Zr. The insulating property in the in-plane direction is maintained by the band gap size and crystalline matrix of the SZO layer 27 even if a current filament path is formed by the transition lines 25 in the film thickness direction.

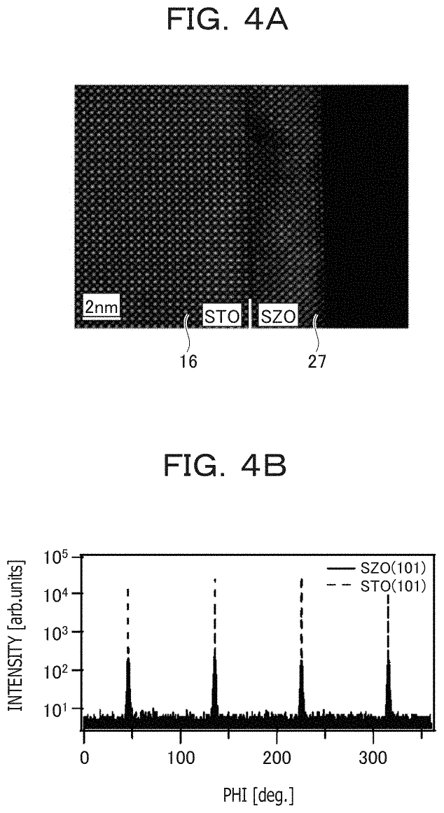

FIGS. 4A and 4B are views illustrating a STEM image of a SZO layer 27 of thickness of 4 nm formed on a STO film and a spectrum of an X-ray diffraction (J) scan, as a comparative example. In the STEM image of FIG. 4A, no transition is observed in the crystal. In the X-ray diffraction of FIG. 4B, an axis is observed four times at the same position in the (101)-oriented SZO layer 27 and the (101)-oriented STO film. It may be seen from this observation that the SZO layer 27 is epitaxial-grown on the STO film in a cube-on-cube manner. It is presumed from FIGS. 3, 4A and 4B that a film thickness region suitable to form a current filament penetrating through the SZO layer 27 in the film thickness direction exists in the SZO layer 27.

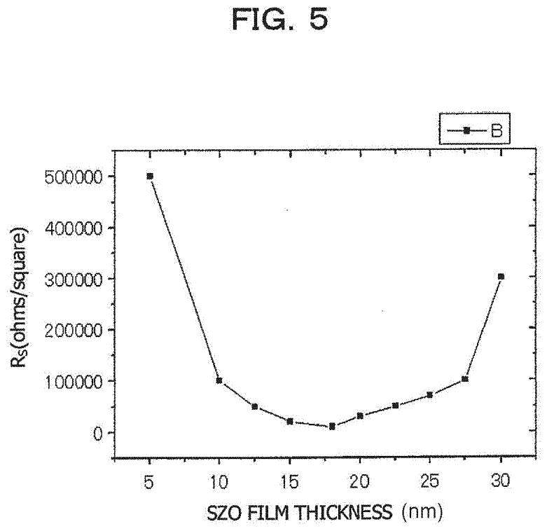

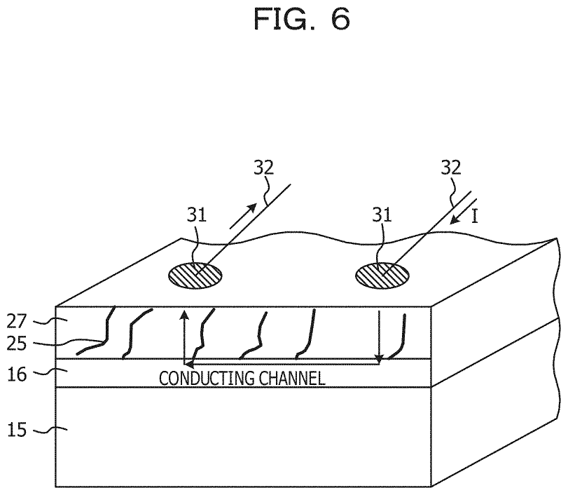

FIG. 5 is a view illustrating a relationship between the film thickness and a sheet resistance of the SZO layer 27 in the hetero structure of FIGS. 2A and 2B. FIG. 6 illustrates a configuration of a sample for making the measurement of FIG. 5. As illustrated in FIG. 6, the hetero structure of the 4 ML La-STO layer 16 and the SZO layer 27 is formed on the LSAT substrate 15. A plurality of samples each having a SZO layer 27 whose thickness is changed from 5 nm to 30 nm is prepared. In each sample, a pair of electrodes 31 is formed on the SZO layer 27, a probe 32 is used to apply a current to one electrode 31, and a voltage is measured from the other electrode 31. If a conductive path by the transition lines penetrating through the SZO layer 27 in the thickness direction is sufficiently formed, the current injected into the one electrode 31 flows through a conducting channel of the La-STO layer 16 via the conductive path by the transition lines 25 and is drawn out of the other electrode 31. The sheet resistance may be calculated from the relationship between the applied current and the measured voltage. Thus, in the uppermost surface of the thin film thermoelectric element using the quantum confinement, a transport and measurement of carriers in the in-plane direction is made possible.

According to a result of the measurement of FIG. 5, the sheet resistance is sufficiently low at the film thickness of 10 nm to 25 nm of the SZO layer 27 and is zero or near zero at the film thickness of 15 nm to 20 nm. The conduction effect by the transition lines in the film thickness direction does not depend on the film thickness of the underlying La-STO layer 16.

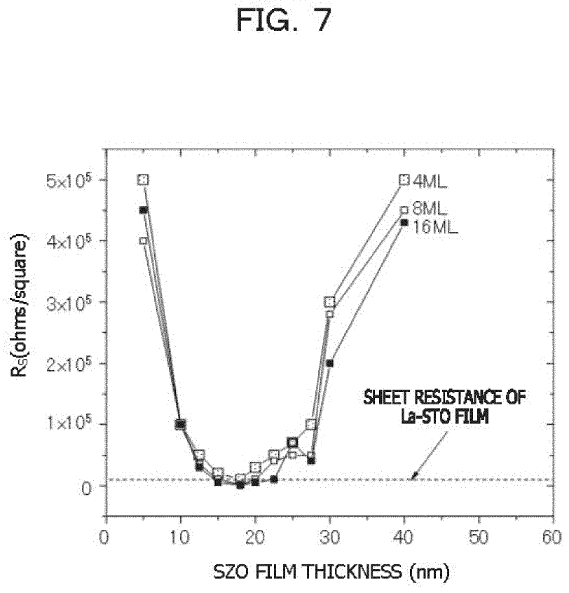

FIG. 7 illustrates the relationship between the film thickness and a sheet resistance of the SZO layer 27 when the thickness of the underlying La-STO layer 16 is changed to 4 ML, 8 ML and 16 ML. In this figure, the dotted line indicates the sheet resistance of the La-STO film. As may be seen from FIG. 7, in a range of the film thickness of the SZO layer 27 from 10 nm to 25 nm, or in the range from 15 nm to 20 nm, the conductivity in the film thickness direction, which is equivalent to that of the La-STO layer 16, may be achieved without depending on the thickness of the underlying La-STO layer 16. If the thickness of the SZO layer 27 is less than 10 nm, the transition lines 25 do not occur (see, e.g., FIGS. 4A and 4B). If the thickness of the SZO layer 27 exceeds 25 nm, a network of the transition lines 25 penetrating from the top to bottom of the SZO layer 27 may not be formed.

As illustrated in FIG. 7, although the sheet resistance of the SZO layer 27 does not depend on the thickness of the underlying La-STO layer 16, from the viewpoint of increasing a Seebeck coefficient S (μV/K), the thickness of the La-STO layer 16 may be set to fall within a range from 1 ML to 12 ML.

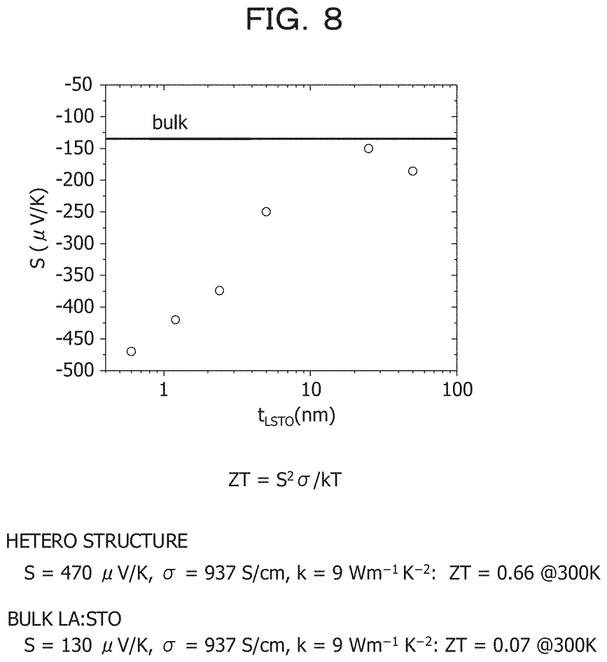

FIG. 8 is a view illustrating the relationship between the thickness of the La-STO layer 16 and the Seebeck coefficient 5, in comparison with a bulk La-STO. When the thickness of the La-STO layer 16 in the hetero structure is 1.5 ML, a (dimensionless) performance index ZT is nine times or more of the bulk La-STO. Even when the thickness of the La-STO layer 16 is 12 ML, the performance index ZT is three times or more of the bulk La-STO.

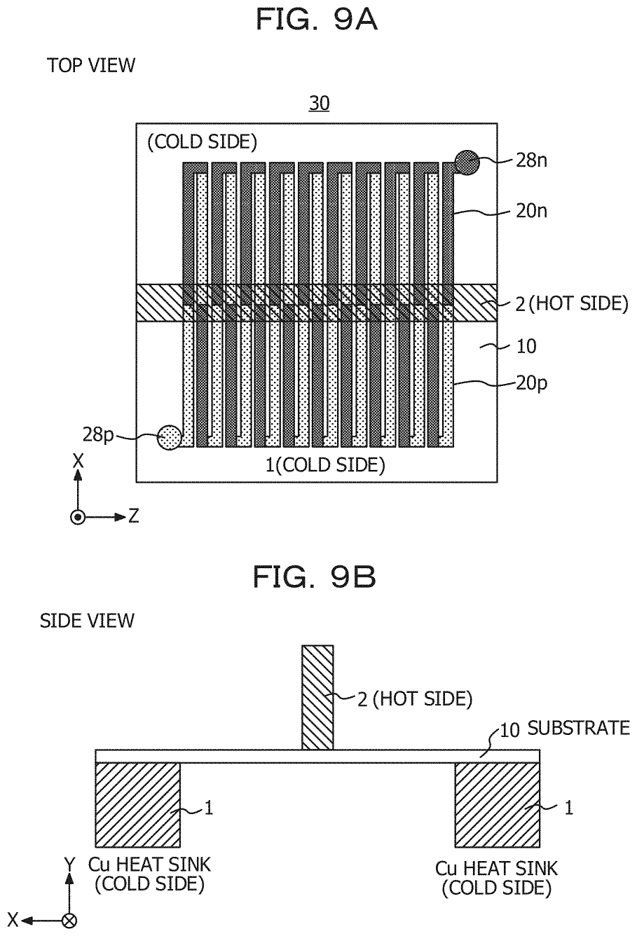

FIGS. 9A and 9B are schematic views of a thin film-type thermoelectric conversion module 30 to which the thermoelectric conversion element 20 of the above embodiment is applied, FIG. 9A being a top (X-Z plane) view and FIG. 9B being a side (X-Y plane) view. An N-type thermoelectric conversion part 20n and a P-type thermoelectric conversion part 20p are alternately connected in series to form a meander pattern. A bent portion of the meander pattern corresponds to a cold side 1 and a central linear portion thereof corresponds to a hot side 2. At the cold side 1, contact electrodes 28n and 28p are disposed on the end portion of the N-type thermoelectric conversion part 20n and the end portion of the P-type thermoelectric conversion part 20p, respectively. The SZO layer 27 having the predetermined thickness range (see, e.g., FIGS. 2A and 2B) is formed to cover the thermoelectric conversion parts 20n and 20p. The SZO layer 27 has the conductivity in the film thickness direction and the insulating property in the in-plane direction, and the contact electrodes 28n and 28p are located on the top surface of the SZO layer 27.

A substrate 10 may be either the LSAT substrate 15 of FIGS. 2A and 2B or any single crystal substrate 10 on which the LSAT layer 15 is formed. When the LSAT substrate 15 is used, the thickness of the substrate 10 is, for example, 10 p.m. When the single crystal substrate 10 on which the LSAT layer 15 is formed is used, the LSAT layer 15 may have any thickness within a range from 1 nm to 10,000 nm. The N-type La-STO layer 16 is formed in a predetermined pattern on the substrate 10 and, subsequently, a P-type perovskite-type oxide layer is formed in a predetermined pattern, thereby providing a pattern shape in which the N-type pattern and the P-type pattern are alternately connected in series. The SZO layer 27 of the thickness of 10 nm to 25 nm is formed on the N-type La-STO layer 16 and the P-type perovskite-type oxide layer by means of a pulse laser epitaxial method, a magnetron sputtering method or the like. Thereafter, the contact electrodes 28n and 28p are formed at predetermined positions on the surface of the SZO layer 27.

Although the characteristics of the SZO layer 27, i.e., the conductivity in the film thickness direction and the insulating property in the in-plane direction, do not depend on the thickness of the underlying N-type La-STO layer 16 and the thickness of the P-type perovskite-type oxide layer, as described above, from the viewpoint of increasing the performance index ZT, the thickness of the La-STO layer 16 and the thickness of the P-type perovskite-type oxide layer may be set to fall within a range from 1 ML to 12 ML.

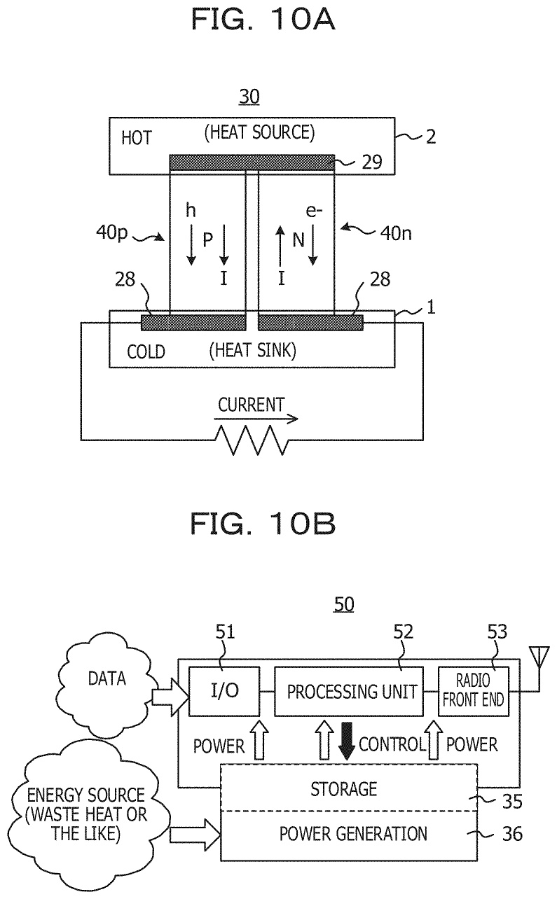

FIG. 10A illustrates the operation principle of the thermoelectric conversion module 30, and FIG. 10B illustrates an example of application of the thermoelectric conversion module 30. As illustrated in FIG. 10A, as an N-type thermoelectric member 40n makes a contact with a heat source of the hot side 2, electrons are activated and move to a cold region. In addition, as a P-type thin film thermoelectric member 40p makes a contact with the heat source of the hot side 2, holes are activated and move to the cold region. As a current I flows in response to a load resistance and a thermos-electromotive force due to a difference in temperature between the hot side 2 and the cold side 1, heat s converted into electric energy. This operation principle is equally applied to the PN junction in the same layer as illustrated in FIGS. 9A and 9B, instead of the serial connection of the N-type thermoelectric member 40n and the P-type thermoelectric member 40p by an electrode 29.

In the example of FIG. 10B, the thermoelectric conversion module 30 is applied to an Information and Communication Technology (ICT) terminal 50 which is energy self-sufficiency. The thermoelectric conversion module 30 is used as a power generator 36 and the electric energy reproduced from waste heat is stored in a storage unit 35. The ICT terminal 50 uses power from the storage unit 35 to operate a data input/output (I/O) unit 51, a processing unit 52, and a radio front end 53. The processing unit 52 may use the power supplied from the storage unit 35 to control the operation of the power generator 36 and the storage unit 35.

Although it has been illustrated in the above embodiment that the thermoelectric material of the N-type thermoelectric conversion element 20 is La-STO, an Nb-STO layer doped with niobium (Nb) replaced with La may be used. In addition, a complex oxide layer including the La-STO layer 16 and a STO film doped with no impurity may be used instead of the single La-STO layer 16. Even in this case, the film thickness of the La-STO layer 16 may be set to fall within a range from 1 ML to 12 ML.

As the second layer 27 having the conductivity in the film thickness direction and the insulating property in the in-plane direction, a perovskite-type oxide which is represented by AZr₁₋ₓBxO₃ and has a band gap of more than 3.5 eV may be used. Instead of SrZrO₃ used in the embodiment, SrZr₁₋ₓTixO₃, LaTiO₃ or the like may be used. In the former, A is Sr and B is Ti. In the latter, A is La, B is Ti and x is 1. Even in the case of these materials, from similarity of a crystal structure and a band gap with SrZrO₃, it is possible to generate transition lines or a transition line network penetrating through the materials with the film thickness of 10 nm to 25 nm in the film thickness direction. The thermoelectric conversion material of the P-type thermoelectric conversion part 20p is not particularly limited but may be CaMnO₃, CaCoO₃, NaCo₂O₃ or the like.

The thermoelectric conversion module 30 of the embodiment may be used for self-feeding of biological sensors, smartphones, etc., in addition to the ICT terminal 50. Further, the thermoelectric conversion module 30 may perform self-feeding using the waste heat in automobiles, or other vehicles which discharge heat.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A thermoelectric conversion module comprising:
a first layer including a perovskite-type oxide of a first conductivity type and a perovskite-type oxide of a second conductivity type, which are coupled in series to form a predetermined pattern;
a second layer of perovskite-type oxide that is formed directly on the first layer in a stacking direction; and
a pair of electrodes formed directly on, and in direct electrical contact with, a top surface of the second layer,
wherein the second layer has a band gap larger than a band gap of the first layer and the pair of electrodes are electrically connected to the first layer by a current path formed by transition lines or a transition line network in the second layer.

2. The thermoelectric conversion module according to claim 1, wherein one of the pair of electrodes is electrically connected to the first layer of the first conductivity type by the transition lines or the transition line network in the second layer
and the other of the pair of electrodes is electrically connected to the first layer of the second conductivity type by the transition lines or the transition line network in the second layer.
